(19) United States
(12) Patent Application Publication
(10) Pub. No.: US 2025/0132225 A1
(43) Pub. Date: Apr. 24, 2025

(54) SEMICONDUCTOR DEVICE

(71) Applicant: HITACHI ASTEMO, LTD., Hitachinaka-shi, Ibaraki (JP)

(72) Inventors: Yusuke TAKAGI, Hitachinaka-shi, Ibaraki (JP); Yujiro KANEKO, Hitachinaka-shi, Ibaraki (JP)

(73) Assignee: HITACHI ASTEMO, LTD., Hitachinaka-shi, Ibaraki (JP)

(21) Appl. No.: 18/834,335

(22) PCT Filed: Mar. 2, 2022
(86) PCT No.: PCT/JP2022/008992

§ 371 Date: Jul. 30, 2024

(51) Int. Cl. H01L 23/40; H01L 25/07; H10D 80/20; H10D 84/80

(52) U.S. Cl. CPC H01L 23/4012; H01L 25/071; H10D 80/231; H10D 80/251; H10D 84/811; H01L 2023/4031; H01L 2023/4087

(57) ABSTRACT

A semiconductor device includes: one or more semiconductor modules arranged in a row; a pair of cooling members disposed so as to sandwich the semiconductor modules and configured to cool the semiconductor modules; a pair of sandwiching members each disposed on an opposite side of the semiconductor module across a corresponding one of the pair of cooling members to oppose the corresponding one of the pair of cooling members; and a coupling portion that couples a pair of sandwiching members to each other and presses each of the pair of sandwiching members against the opposing one of the cooling members, in which at least one of the pair of sandwiching members includes a plurality of support portions disposed to oppose ends of the arranged semiconductor modules and a space between the semiconductor modules, and a spring portion extending from each of the plurality of support portions in an arrangement direction of the semiconductor modules and abutting the cooling member, and the coupling portion couples the support portion provided to the one of the pair of sandwiching members and another sandwiching member.

### TECHNICAL FIELD

The present invention relates to a semiconductor device including a semiconductor module.

### BACKGROUND ART

Patent Literature 1 discloses a configuration in which a power module including a stacked body of a semiconductor device including a semiconductor element and a cooler is sandwiched between a pair of sandwiching members having curved portions, and the stacked body is pressed in a stacking direction by reactive force of elastic deformation at the curved portions.

### CITATION LIST

### Patent Literature

PTL 1: JP 2021-005603 A

### SUMMARY OF INVENTION

### Technical Problem

In the technique of PTL 1, the sandwiching members are fixed to each other with fixing members from two sides in a direction that is orthogonal to the stacking direction of the stacked body and is the direction in which terminals are not drawn out. The sandwiching member has two curved portions, each between two of three base portions, and the base portions at the two ends are biased in a direction toward the cooler by the fixing portions, whereby the curved portions are elastically deformed. However, the base portion at the center connected to the curved portions, among the three base portions, is not biased in the direction toward the cooler by the fixing portions, so that the elastic deformation of the curved portions may be insufficient. That is, the quake resistance for holding the cooler is insufficient.

### Solution to Problem

A semiconductor device according to an aspect of the present invention includes: one or more semiconductor modules arranged in a row; a pair of cooling members disposed so as to sandwich the one or more semiconductor modules arranged in a row and configured to cool the semiconductor modules; a pair of sandwiching members each disposed on an opposite side of the semiconductor module across a corresponding one of the pair of cooling members to oppose the corresponding one of the pair of cooling members; and a coupling portion that couples the pair of sandwiching members to each other and presses each of the pair of sandwiching members against the opposing one of the cooling members, wherein at least one of the pair of sandwiching members includes a plurality of support portions disposed to oppose ends of the one or more semiconductor modules arranged in a row and a space between the semiconductor modules, and a spring portion extending from each of the plurality of support portions in an arrangement direction of the semiconductor modules and abutting the cooling member, and the coupling portion couples the support portion provided to the one of the pair of sandwiching members and another sandwiching member.

### Advantageous Effects of Invention

According to the present invention, quake resistance can be improved.

### BRIEF DESCRIPTION OF DRAWINGS

FIG. 1 is a circuit diagram for explaining a circuit configuration of a semiconductor module provided in a semiconductor device.

FIG. 2 is an external perspective view of the semiconductor module.

FIG. 3 is an A-A cross-sectional view in FIG. 2.

FIG. 4 is an external perspective view of the semiconductor device.

FIG. 5 is an exploded perspective view of the semiconductor device.

FIG. 6 is a cross-sectional view illustrating a part of a B cross section in FIG. 5.

FIG. 7 is a C-C cross-sectional view in FIG. 6.

FIG. 8 is a D-D cross-sectional view in FIG. 6.

FIG. 9 is a view illustrating an assembly procedure of a cooling unit.

FIG. 10 is a view for explaining attaching a coupling member in the assembly procedure of the cooling unit.

FIG. 11 illustrates a first exemplary modification, and is a perspective view of a semiconductor device.

FIG. 12 is a cross-sectional view illustrating an E cross section in FIG. 11.

FIG. 13 is a figure illustrating a second exemplary modification, and is a perspective view of a semiconductor device.

### DESCRIPTION OF EMBODIMENTS

Embodiments of a semiconductor device according to the present invention will be described with reference to the drawings. The following description and drawings are examples for describing the present invention. Omission and simplification are made as appropriate for clarity of description. In the following description, the same or similar elements or processes are denoted by the same reference numeral, and redundant description may be omitted. Note that the contents described below are merely examples of embodiments of the present invention, and the present invention is not limited to the following embodiments, and can be implemented in other various forms.

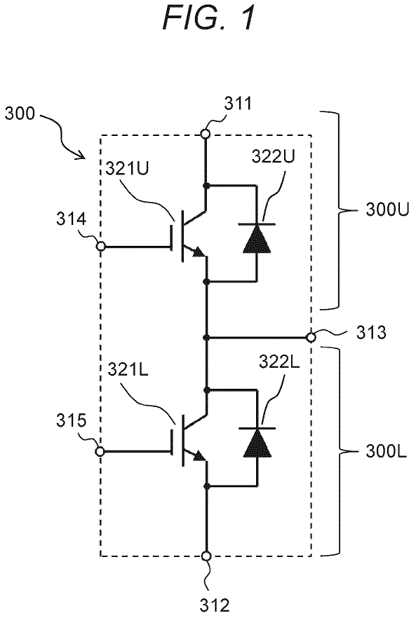

FIG. 1 is a circuit diagram for explaining a circuit configuration of a semiconductor module 300 provided in a semiconductor device. The semiconductor device of the present embodiment is provided, for example, in an inverter circuit of a power conversion apparatus mounted on an electric vehicle, a hybrid vehicle, or the like. The power conversion apparatus converts power between a DC power supply and a motor generator (for example, a three-phase AC type rotating electric machine) that makes a vehicle travel. The power conversion apparatus includes a smoothing capacitor and an inverter circuit that is a power converter. The inverter circuit converts an input DC power into a three-phase AC of a predetermined frequency, and outputs the three-phase AC to the motor generator. The inverter circuit includes, for example, semiconductor modules for three phases. FIG. 1 illustrates a circuit diagram of the semiconductor module 300 for one phase.

The circuit of the semiconductor module 300 includes an upper arm 300U and a lower arm 300L connected in series. The upper arm 300U includes a power semiconductor element 321U and a diode 322U. The lower arm 300L includes a power semiconductor element 321L and a diode 322L. The power semiconductor elements 321U and 321L include, for example, an insulated gate bipolar transistor (IGBT), a field effect transistor (FET), or the like. The power semiconductor element 321U of the upper arm 300U is on-off controlled by a control signal input to an upper arm control terminal 314. Likewise, the power semiconductor element 321L of the lower arm 300L is on-off controlled by a control signal input to a lower arm control terminal 315.

An external connection P terminal 311 of the upper arm 300U is connected to a high potential power line of the DC power supply, and an external connection N terminal 312 of the lower arm 300L is connected to a low potential power line of the DC power supply. An external connection AC terminal 313 is provided at a connection point between the upper arm 300U and the lower arm 300L, and an alternating current is output from the external connection AC terminal 313 to an external device (for example, a motor). A capacitor or the like is connected to a DC power supply line in parallel with the upper and lower arms 300U and 300L.

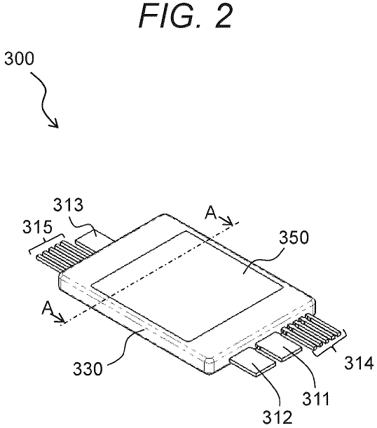

FIG. 2 is an external perspective view of the semiconductor module 300. The power semiconductor elements 321U and 321L, the diodes 322U and 322 L, and the like of the semiconductor module 300 are sealed with a sealing resin 330 formed of an electrically insulating material. The external connection P terminal 311, the external connection N terminal 312, the external connection AC terminal 313, the upper arm control terminal 314, and the lower arm control terminal 315 are exposed out of the sealing resin 330. A heat conduction member 350 is provided on each of the two surfaces of the semiconductor module 300 which is a circuit molded body.

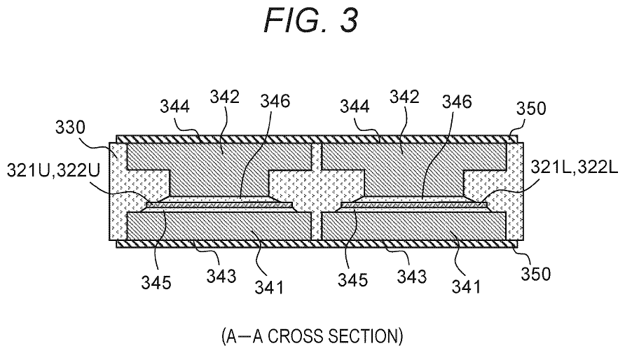

FIG. 3 is an A-A cross-sectional view in FIG. 2. The main surface of each of the power semiconductor elements 321U and 321L and the diodes 322U and 322L is bonded to a heat sink 341 via a bonding material 345. The surface opposite to the main surface of each of the power semiconductor elements 321U and 321L and the diodes 322U and 322L is bonded to a heat sink 342 via a bonding material 346. Solder or a sintered material is used as the bonding materials 345 and 346. As the heat sinks 341 and 342, a metal such as copper and aluminum, an insulating substrate having a copper wiring, or the like is used. The sealing resin 330 seals the power semiconductor elements 321U and 321L, the diodes 322U and 322L, the heat sinks 341 and 342, and the bonding materials 345 and 346.

A heat dissipating surface 343 is provided on a surface of the heat sink 341 opposite to the surface bonded to the bonding material 345. A heat dissipating surface 344 is provided on a surface of the heat sink 342 opposite to the surface bonded to the bonding material 346. The heat dissipating surfaces 343 and 344 are exposed out of the sealing resin 330. Each of the heat dissipating surface 343 and the heat dissipating surface 344 is in tight contact with a heat conduction member 350. A resin, ceramic, or the like exhibiting insulating performance is used as the heat conduction member 350. When a ceramic is used as the heat conduction member 350, the heat conduction member 350 are brought into tight contact with the heat dissipating surfaces 343 and 344 of the circuit molded body and cooling members 110 and 210 described later with grease or the like therebetween. Although not illustrated, in a case where an insulating substrate or a resin insulating member is provided to be in tight contact with the heat sinks 341 and 342, grease is used as the heat conduction member 350. Heat generated in the semiconductor module 300 is radiated to the cooling members 110 and 210 via the heat conduction member 350.

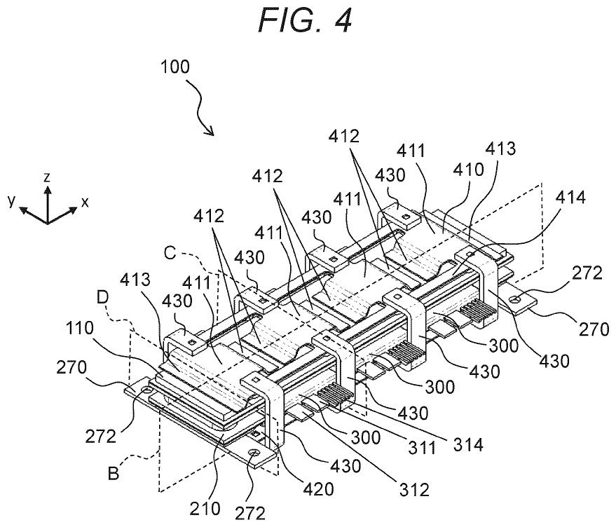

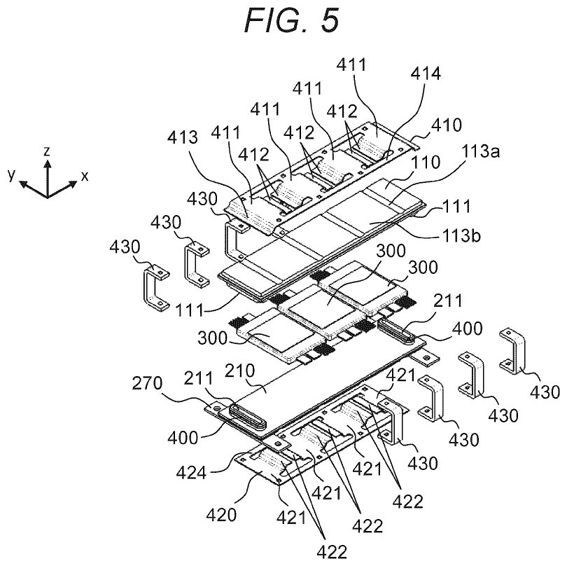

An overall configuration of a semiconductor device 100 will be described with reference to FIGS. 4 to 8. FIG. 4 is an external perspective view of the semiconductor device 100. FIG. 5 is an exploded perspective view of the semiconductor device 100. As illustrated in FIG. 5, in the semiconductor device 100, three semiconductor modules 300 constituting a three-phase inverter circuit are arranged in a row in x direction, and a cooling unit for cooling the semiconductor modules 300 is provided. The cooling unit includes a pair of cooling members 110 and 210, a pair of sandwiching members 410 and 420, and a plurality of coupling members 430. The semiconductor device 100 illustrated in FIG. 4 includes the semiconductor modules 300 for three phases, but may include the semiconductor module for only one phase, for example.

The cooling members 110 and 210 are disposed so as to sandwich from front and back sides in z direction a plurality of semiconductor modules 300 arranged in the x direction. As described later, flow paths in which a refrigerant flows are formed in the cooling members 110 and 210. Although not illustrated, inlets and outlets for the refrigerant are provided in the cooling members 110 and 210. The refrigerant is supplied from the external. As illustrated in FIG. 5, the cooling member 110 is provided with, at two ends on a surface facing the cooling member 120, flow path connections 111 to be connected to flow path connections 211 of the cooling member 210. By connecting the flow path connections 111 to the flow path connections 211, the flow path in the cooling member 110 and the flow path in the cooling member 210 communicate with each other. On a lower surface, in the drawing, of the cooling member 210, a flange 270 is provided to connect a case (not illustrated) for supplying the refrigerant. A mounting hole 272 through which a fastening member such as a screw is inserted is formed in the flange 270.

As illustrated in FIG. 4, the external connection P terminal 311, the external connection N terminal 312, the external connection AC terminal 313, the upper arm control terminal 314, and the lower arm control terminal 315 of each semiconductor module 300 are drawn out in y direction orthogonal to the arrangement direction of the semiconductor modules 300. The sandwiching member 410 is disposed on the opposite side of the semiconductor module 300 across the cooling member 110, that is, on the z directional plus side of the cooling member 110, so as to face the cooling member 110. The sandwiching member 420 is disposed on the opposite side of the semiconductor module 300 across the cooling member 210, that is, on the z directional minus side of the cooling member 210, so as to face the cooling member 210.

The sandwiching member 410 is formed of a single plate member (for example, a metal plate material), and includes a plurality of support portions 411, a frame portion 414, and spring portions 412 and 413. A plurality of support portions 411 extending in the y direction are arranged side by side in the arrangement direction of the semiconductor modules 300 (x direction) and oppose two ends of the x directional arrangement of the three semiconductor modules 300 and spaces between the modules. The ends of the support portions 411 are connected to each other by the frame portion 414 extending in the x direction. The spring portions 412 and 413 are formed at two ends in the arrangement direction (x direction) of each support portion 411. The spring portions 412 and 413 extend in the x direction from the support portion 411 and abut the cooling member 110. Note that the spring portion 413 is provided only to the two support portions 411 disposed on the most x directional minus side and the most x directional plus side in the module arrangement. A plurality of spring portions 412 and 413 is arranged such that the two spring portions 413 are on the most x directional minus side and the most x directional plus side in the module arrangement.

The sandwiching member 420 is configured substantially the same as the sandwiching member 410. That is, there is a plurality of support portions 421 disposed in the arrangement direction of the semiconductor modules 300 (x direction), and the ends of the support portions 421 are connected to each other by a frame portion 424 extending in the x direction. The support portion 421 has the spring portion 422 extending in the x direction and abutting the cooling member 210. The two support portions 421 disposed on the most x directional minus side and the most X directional plus side in the module arrangement of the sandwiching member 420 each have only one spring portion 412. Of course, as in the case of the support portion 411 of the sandwiching member 410, the support portion 421 may have two spring portions.

A plurality of coupling members 430 presses a pair of sandwiching members 410 and 420 against the respective opposing cooling members 110 and 210. As a result, the cooling members 110 and 210 are held so as to be pressed against the respective front and back surfaces of a plurality of semiconductor modules 300. The coupling members 430 are disposed on the sides, facing the lateral direction (y direction), of the sandwiching members 410 and 420 a substantially equal intervals in the longitudinal direction (x direction) of the sandwiching members 410 and 420.

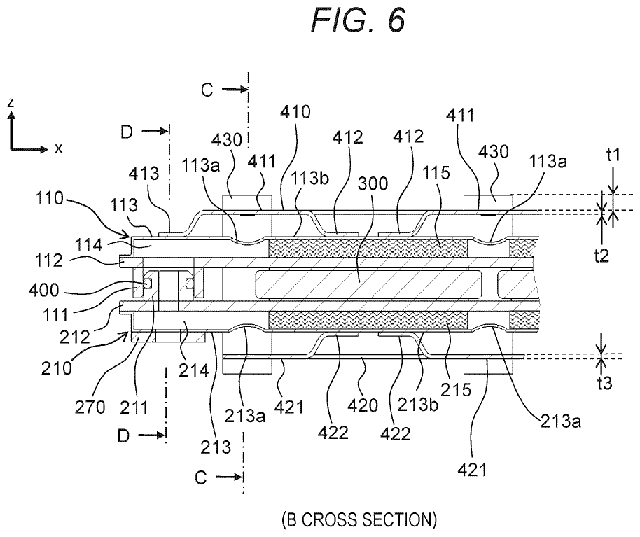

FIG. 6 is a view illustrating a part of a B cross section taken along a plane B in FIG. 5, and is a cross-sectional view of a portion including the flow path connection 111, the flow path connection 211, and the semiconductor modules 300 adjacent to the flow path connection 111 and the flow path connection 211. The three semiconductor modules 300 are arranged side by side in the left-right direction (x direction) in the drawing, and are sandwiched by the cooling members 110 and 210 disposed above and below. The sandwiching member 410 is disposed on the upper side of the cooling member 110 in the drawing, and the sandwiching member 420 is disposed on the lower side of the cooling member 210 in the drawing. A plurality of coupling members 430 is attached to press the sandwiching members 410 and 420 against the respective opposing cooling members 110 and 210.

The cooling member 110 is formed by joining a cover 113 to a base 112 to form a flow path 114. A fin 115 is provided in the flow path 114 in a region where the cooling member 110 opposes the semiconductor module 300. The heat of the semiconductor module 300 is released to the refrigerant in the flow path 114 via the base 112 in tight contact with the module upper surface. With the fin 115 provided in the region in the flow path 114 opposing the semiconductor module 300, heat is more efficiently transferred from the semiconductor module 300 to the refrigerant. As illustrated in FIG. 6, no fin 115 is provided in a region where the flow path connection 111 is provided and thus cooling is unnecessary, so that the pressure loss of the refrigerant can be reduced.

The flow path connection 111 described above is provided on the lower surface of an end region on the left side in the drawing of the base 112. The flow path connection 111, the base 112, the cover 113, and the fin 115 are formed of aluminum, an aluminum alloy, copper, a copper alloy, or the like, and are joined by brazing. Instead of brazing, an adhesive may be used for bonding. The cover 113 has an opposing portion 113b on which the fin 115 is provided and which opposes the semiconductor module 300, and recessed portions 113a provided in regions at two ends of the opposing portion 113b. With the recessed portion 113a provided in a region where no fin 115 is provided, the rigidity against bending of the cooling member 110 at the region where the recessed portion 113a is provided can be reduced to be smaller than the rigidity in the region of the opposing portion 113b where the fin 115 is provided.

The cooling member 210 also has a configuration similar to the cooling member 110, and includes a base 212 and a cover 213 forming the flow path 214. A plurality of fins 215 is provided in the flow path 214, and the cover 213 has recessed portions 213a and opposing portions 213b. On the upper surface of the base 212 in the drawing, a flow path connection 211 is provided at a place opposing the flow path connection 111 of the cooling member 110. The flow path connection 211 provided with a sealing material 400 is inserted into the flow path connection 111 in a water-tight manner. Thus, the flow path 114 of the cooling member 110 and the flow path 214 of the cooling member 210 communicate with each other. The flange 270 is fixed to each of the left end and the right end of the lower surface of the cover 213 (see FIG. 5). The base 212 is in tight contact with the illustrated lower surface of the semiconductor module 300. Also in the cooling member 210, no fin 215 is provided in the region where the flow path connection 211 that needs no cooling is provided, so that the pressure loss of the refrigerant can be reduced.

The sandwiching member 410 is disposed on the upper side of the cooling member 110 in the drawing, and the sandwiching member 420 is disposed on the lower side of the cooling member 210 in the drawing. In FIG. 6, the sandwiching member 410 is illustrated with the support portion 411 disposed on the leftmost side in the drawing and the adjacent support portion 411, and the sandwiching member 420 is illustrated with the support portion 421 disposed on the leftmost side in the drawing. The support portions 411 and 421 disposed on the leftmost side in the drawing are support portions opposing the left end of a single row arrangement of a plurality of semiconductor modules 300. The adjacent support portion 411 on the right side in the drawing is a support portion disposed to oppose the space between two semiconductor modules 300.

Regarding the support portions 411 and 421 disposed to oppose the left end of the module arrangement, the support portion 411 has the spring portion 412 extending in the x directional plus side and the spring portion 413 extending in the x directional minus side. Meanwhile, the support portion 421 has only the spring portion 412 extending in the x directional plus side. The support portions 411 and 421 disposed to oppose the space between modules of the module arrangement respectively have a pair of spring portions 412 respectively extending in the x directional plus side and the x directional minus side and a pair of spring portions 422 respectively extending in the x directional plus side and the x directional minus side. In FIG. 6, illustration of the spring portions 412 and 422 extending in the x directional plus side is omitted.

The spring portion 412 abuts a portion of the cover 113 where the fin 115 is provided, that is, abuts a place on the cooling member 110 opposing the semiconductor module 300. As can be seen from FIGS. 5 and 6, two spring portions 412 extending from the two support portions 411 abut a region in the cooling member 110 opposing the semiconductor module 300. Meanwhile, the spring portion 413 abuts a portion of the cover 113 where the flow path connection 111 is provided. The spring portion 412 and the spring portion 413 have different spring constants. As for the sandwiching member 420 opposing the cooling member 210, two spring portions 422 extending from the two support portions 421 abut a region in the cooling member 210 opposing the semiconductor module 300. The spring constant of the spring portion 422 is set, for example, to be substantially the same as the spring constant of the spring portion 412.

The regions in the cooling members 110 and 210 opposing the semiconductor module 300 are pressed against the semiconductor modules 300 by the reactive force of the spring portions 412, 413, and 422. As described above, the sandwiching members 410 and 420 press regions in the cooling members 110 and 210 opposing the semiconductor modules 300 in directions toward the semiconductor modules 300. Therefore, even when the cooling members 110 and 210 or the semiconductor modules 300 are warped or vary in thickness, the regions in the cooling members 110 and 210 opposing the semiconductor modules 300 are each pressed against the semiconductor module 300 in a manner corresponding to warpage or variation in thickness. That is, the cooling members 110 and 210 are each uniformly pressed against the semiconductor modules 300. When heat is generated, the members constituting the semiconductor module 300 may deform by differences in linear expansion coefficient among the members, but such deformation is suppressed since the pressing force is independently applied to each semiconductor module 300, which improves the reliability of the product.

As described above, in the cooling members 110 and 210, the region provided with the recessed portion 113a or 213a has lower rigidity than the region provided with the opposing portion 113b or 213b and thus is easily bent. Therefore, even when there is variation in thickness and warpage among a plurality of semiconductor modules 300, the region with the recessed portion 113a or 213a is bent to readily create a tight contact with the semiconductor modules 300, whereby the cooling performance can be improved.

As illustrated in FIG. 6, the spring portion 413 extending from the support portion 411 on the left side in the drawing to the x directional minus side abuts the cover 113 at the region provided with the flow path connection 111. When the refrigerant flows in the cooling members 110 and 210 sandwiching the semiconductor modules 300, the pressure of the refrigerant creates such a force that separates the cooling members 110 and 210 from the semiconductor modules 300. The pressing force of the spring portions 413 can reduce this separating effect. The pressing force of the spring portion 412 pressing the portion provided with the fin 115 against the semiconductor module 300 is set different from the pressing force of the spring portion 413. By setting different spring constants for the spring portions 412 and 413, different pressing forces can be produced.

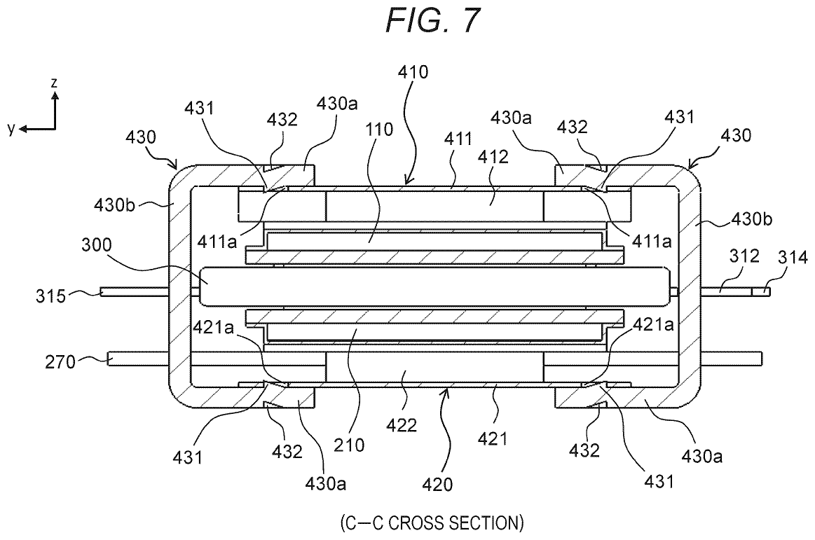

The sandwiching member 410 and the sandwiching member 420 are coupled by the coupling members 430 which are separate members, and are pressed against the respective opposing cooling members 110 and 210 by the coupling members 430. FIG. 7 is a C-C cross-sectional view in FIG. 6. The C-C cross section is taken along the lateral direction of the sandwiching members 410 and 420 and the cooling members 110 and 210 (y direction), and a plurality of coupling members 430 is disposed on sides facing the lateral direction of the sandwiching members 410 and 420 and the cooling members 110 and 210. The coupling member 430 has engaging portions 430a that engage with the support portions 411 and 421 and a connecting portion 430b that connects the two engaging portions 430a. The engaging portions 430a provided at the upper and lower ends of the connecting portion 430b extend toward the sandwiching members 410 and 420 from the connecting portion 430b located at the side facing the y direction.

Projections 431 are formed on surfaces of the two engaging portions 430a opposing the support portions 411 and 421. The projection 431 is formed by press working or the like. The projection 431 of the engaging portion 430a on the upper side in the drawing engages with a hole 411a in the support portion 411 of the sandwiching member 410. The projection 431 of the engaging portion 430a on the lower side in the drawing engages with a hole 421a in the support portion 421 of the sandwiching member 420. Instead of the holes 411a and 421a, recessed portions with which the projections 431 can engage may be provided. As described above, the projections 431 engage with the holes 411a and 421a to prevent disengaging of the coupling member 430 from the sandwiching members 410 and 420.

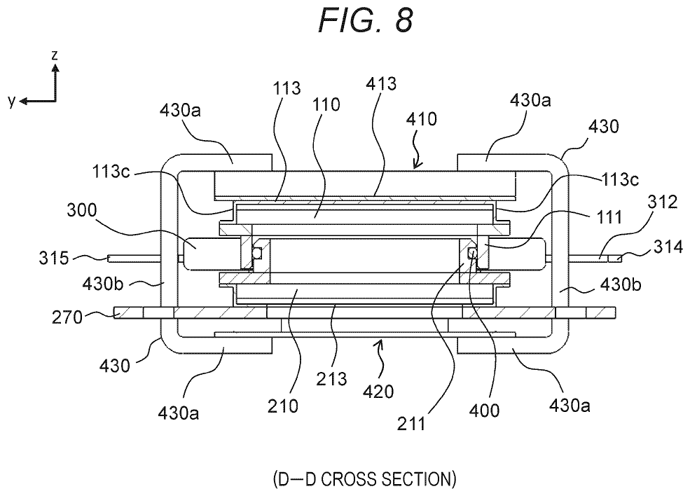

FIG. 8 is a D-D cross-sectional view in FIG. 6. There is no fin 115 provided inside the cover 113 in the region where the spring portion 413 abuts, unlike the covered region where the spring portion 412 abuts as in FIG. 7. However, as illustrated in FIG. 5, the spring portion 413 having a larger dimension in the y direction than that the spring portion 412 also abuts a part of a side wall 113c, erecting in the z direction, of the cover 113. Therefore, the side wall 113c suppresses deformation of the cover 113.

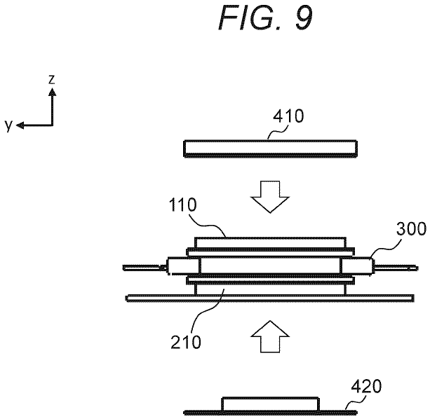

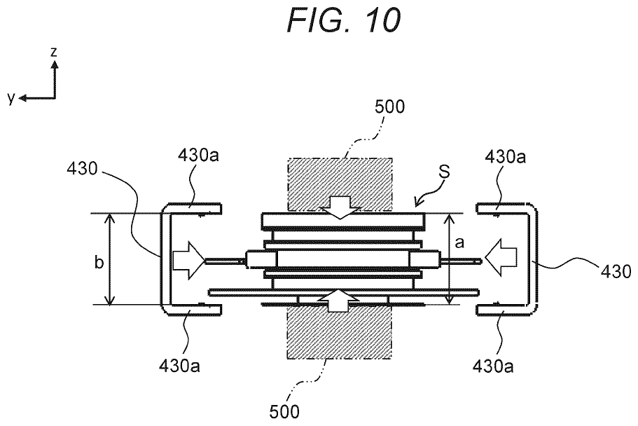

FIGS. 9 and 10 are views illustrating the assembly procedure of the sandwiching members 410 and 420 and the coupling members 430. First, the cooling members 110 and 210 are disposed on the front and back surfaces, facing the thickness direction (z direction in FIG. 9), of a plurality of semiconductor modules 300 arranged in a row in the x direction to create a stacked state in which a plurality of semiconductor modules 300 are sandwiched between the cooling members 110 and 210. Then, the sandwiching member 410 is disposed on the upper side of the cooling member 110 in the drawing, and the cooling member 420 is disposed on the lower side of the cooling member 210 in the drawing to form a stacked body S as illustrated in FIG. 10.

Next, as illustrated in FIG. 10, the stacked body S is compressed in the up-down direction using a pair of pressing jigs 500, and a plurality of coupling members 30 are attached. In this state, the support portions 411 and 421 of the sandwiching members 410 and 420 are pressed in the respective directions toward the opposing cooling members 110 and 210, and the spring portions 412, 413, and 422 provided to the support portions 411 and 421 are elastically deformed. As a result, a thickness dimension a (that is, the dimension in the z direction) of the stacked body S decreases. The stacked body S is compressed by the pressing jigs 500 such that the thickness dimension a of the stacked body S becomes substantially the same as or slightly smaller than a space b between a pair of engaging portions 430a of the coupling member 430, and the coupling members 430 are attached from sides facing the lateral direction of the stacked body S so as to sandwich the stacked body S as illustrated in FIG. 10.

When the coupling member 430 is attached, the projections 431 of the two upper and lower engaging portions 430a respectively engage with the hole 411a in the support portion 411 and the hole 421a in the support portion 421 (see FIG. 7). The jigs 500 are then removed from the stacked body S. When the jigs 500 are removed, the support portions 411 and 421 are pressed against the engaging portions 430a by the reactive force of the elastically deformed spring portions 412 and 422. As a result, the cooling members 110 and 210 are held to sandwich the semiconductor modules 300.

The rigidity of the coupling member 430 is set higher than the rigidity of the support portions 411 and 421 provided with the spring portions 412, 413, and 422 so as not to deform by the reactive force of the spring portions 412, 413, and 422. For example, the coupling members 430 and the sandwiching members 410 and 420 are formed of metal plates, but as illustrated in FIG. 6, when the sandwiching members 410 and 420 respectively have a thickness t2 and a thickness t3, a thickness t1 of the coupling member 430 is set larger than t2 and t3. By pressing the support portions 411 and 421 with the coupling members 430 having a high rigidity, the pressing force of the spring portions 412, 413, and 422 acting on the cooling members 110 and 210 can be further increased. As a result, the pressing force by which the cooling members 110 and 210 are pressed against the semiconductor modules 300 can be increased, whereby the reliability of cooling performance can be improved.

In the above-described embodiment, one of a plurality of support portions 411 provided with the spring portions 412 and one of a plurality of support portions 421 provided with the spring portions 422 that face each other are coupled by the coupling members 430. This further increases the pressing force of the spring portions 412 and 422 that presses the cooling members 110 and 210 in the directions toward the semiconductor modules 300, where by the quake resistance for holding the cooling members 110 and 210 can be improved.

In the above-described embodiment, the semiconductor device 100 includes a plurality of semiconductor modules 300, but the present invention can also be applied to a case with one semiconductor module 300. In this case, although not illustrated, the sandwiching members 410 and 420 are respectively provided with support portions 411 and 421 disposed at two x directional sides of the semiconductor module 300, the x direction being orthogonal to the y direction along which the terminal 311 and the like of the semiconductor module 300 in FIGS. 4 and 5 are drawn out. Each support portion 411 has spring portions 412 and 413, and each support portion 421 has a spring portion 422. The cooling member 110 has a pair of recessed portions 113a provided on two sides of an opposing portion 113b, and the cooling member 210 has a pair of recessed portions 213a provided on two sides of an opposing portion 213b. The region of the opposing portion 113b of the cooling member 110 is pressed against the semiconductor module 300 by the two spring portions 412. The region of the opposing portion 213b of the cooling member 210 is pressed against the semiconductor module 300 by the two spring portions 422.

### First Exemplary Modification

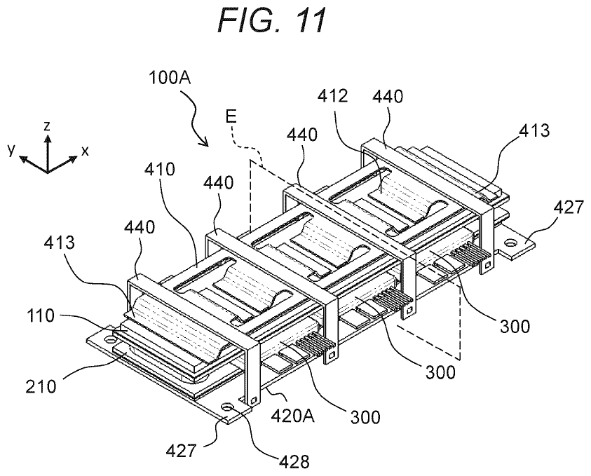

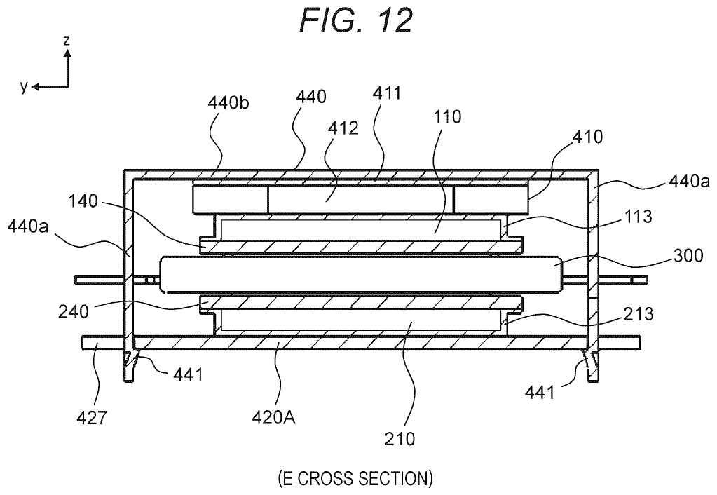

FIGS. 11 and 12 are views illustrating a first exemplary modification of the embodiment described above. FIG. 11 is a perspective view of a semiconductor device 100A, and FIG. 12 is a cross-sectional view taken along a plane E in FIG. 11. The first exemplary modification is different from the embodiment described above in that a sandwiching member 420A is used instead of the sandwiching member 420 and coupling members 440 is used instead of the coupling members 430. A plurality of semiconductor modules 300, cooling members 110 and 210, and a sandwiching member 410 respectively have the same configurations as those of the embodiment described above. Different configurations will be mainly described below.

The sandwiching member 420A is bonded to a z directional minus side (lower side in FIG. 12) of the cooling member 210. Note that the sandwiching member 420A may be simply disposed on the lower side instead of being bonded to the cooling member 210. Flanges 427 each provided with a mounting hole 428 are formed at two x directional ends of the sandwiching member 420A. The coupling member 440 includes a pair of engaging portions 440a and a connecting portion 440b connecting the engaging portions 440a. A projection 441 for engagement is formed on each engaging portion 440a.

As described above, in the first exemplary modification, a single sandwiching member 420A serves as a pair of flanges 270 and the sandwiching member 420 of the embodiment described above, and the sandwiching member 420A is a simple plate member. In other words, the first exemplary modification has a configuration in which the sandwiching member 420 is eliminated to be replaced with a plate member (sandwiching member 420A) having the flanges 270 at two ends thereof and extending in the x direction.

To attach the coupling members 440, each of a plurality of coupling members 440 are brought into contact with the corresponding support portion 411, and all the coupling members 440 are pressed downward in the drawing using a pressing jig. Consequently, the spring portions 412 are deformed and the inclined surface of the projection 441 is pressed against a y directional end surface of 420A, thereby increasing the space between a pair of engaging portions 440a. By further pushing down the coupling member 440, the projection 441 engages with the lower surface side of the sandwiching member 420A.

As described above, also in the first exemplary modification, each region, opposing the semiconductor modules 300, of the cooling member 110 is pressed against the semiconductor module 300 by the spring portion 412 of the sandwiching member 410, so that the cooling member 110 is appropriately pressed against the semiconductor modules 300. In addition, pressing each of the support portions 411 in the direction toward the cooling member 10 by the connecting portion 440b of the corresponding coupling member 440 prevents deformation of the support portion 411 caused by the reactive force of the spring portion 412, and thus the pressing force of the spring portions 412 can be increased. Furthermore, in the first exemplary modification, since the sandwiching member 420A which is a plate member having a simple shape replaces a pair of flanges 270 and the sandwiching member 420 having a complex shape, the cost can be reduced.

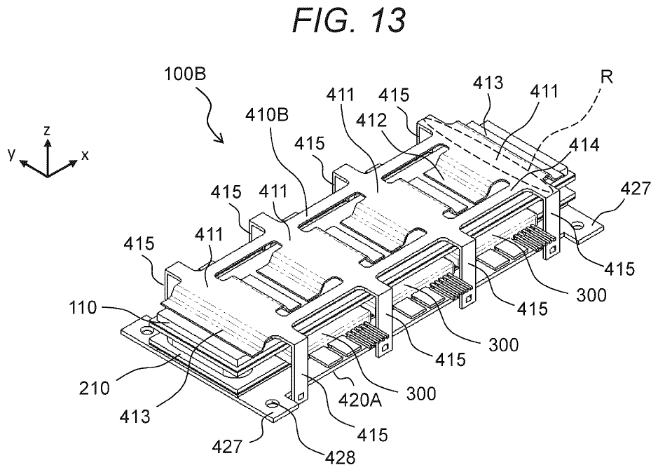

In the example illustrated in FIG. 11, the sandwiching member 420A may not be bonded to the cooling member 210, and the sandwiching member 420 illustrated in FIGS. 4 and 5 may be disposed between the sandwiching member 420A and the cooling member 210. Furthermore, the coupling member 440 of the first exemplary modification can be applied also to the embodiment illustrated in FIGS. 4 and 5. That is, in FIGS. 4 and 5, the coupling member 440 in FIG. 13 is used instead of the coupling member 430. The engaging portion 440a of the coupling members 440 are engaged with the lateral ends of the sandwiching members 420. In this case, two ends of the support portion 421 of the sandwiching member 420 are extended in the lateral direction beyond the cooling members 110 and 210, and the engaging portions 440a are engaged with the extended portion of the support portions 421.

### Second Exemplary Modification

FIG. 13 is a figure illustrating a second exemplary modification, and is a perspective view of a semiconductor device 100B. In the second exemplary modification, a coupling member is integrally formed with a sandwiching member 410A. Other configurations are the same as those of the first exemplary modification described above, and the description thereof will be omitted. As indicated by broken line R, two ends of each support portion 411 extending in the y direction extend in the lateral direction beyond cooling members 110 and 210. At the two ends of each support portion 411 in the extending direction thereof, coupling portions 415 are formed to extend in the z direction. The coupling portion 415 has the same shape as the engaging portion 440a of the coupling member 440 of the first exemplary modification. A sandwiching member 420A, a cooling member 210, a plurality of semiconductor modules 300, a cooling member 110, and a sandwiching member 410B are stacked, and by pressing the sandwiching member 410B in the direction toward the cooling member 110 by a pressing jig, each of the coupling portions 415 engages with the corresponding lateral end of the sandwiching member 420A. In the second exemplary modification, the coupling portions 415 and the sandwiching member 410B are integrally formed, so that the number of parts can be reduced as compared with the first exemplary modification, and this further gives excellent workability for assembling.

In a case of the second exemplary modification, the sandwiching member 420A may not be bonded to the cooling member 210, and the sandwiching member 420 illustrated in FIGS. 4 and 5 may be disposed between the sandwiching member 420A and the cooling member 210. Furthermore, the sandwiching member 410B of the second exemplary modification can be applied also to the embodiment illustrated in FIGS. 4 and 5. That is, in FIGS. 4 and 5, the sandwiching member 410B in FIG. 13 is used instead of the sandwiching member 410 and the coupling member 430. The coupling portions 415 of the sandwiching member 410B are engaged with the lateral ends of the sandwiching member 420. In this case, like the support portion 411 in FIG. 13, two ends of the support portion 421 of the sandwiching member 420 are extended in the lateral direction beyond the cooling members 110 and 210.

According to the embodiment and the exemplary modifications of the present invention described above, the following effects are obtained.

(C1) As illustrated in FIGS. 11 and 12, the semiconductor device 100A includes a plurality of semiconductor modules 300 arranged in a row, a pair of cooling members 110 and 210 disposed so as to sandwich a plurality of semiconductor modules 300 arranged in a row to cool the semiconductor modules 300, a pair of sandwiching members 410 and 420A each disposed on the opposite side of the semiconductor module across the corresponding one of a pair of cooling members 110 and 210 to oppose the corresponding one of a pair of cooling members 110 and 210, and a plurality of coupling members 440 as a coupling portion that couples a pair of sandwiching members 410 and 420A to each other to press each of the sandwiching members 410 and 420A against the opposing one of the cooling members 110 and 210. The sandwiching member 410, which is one of a pair of sandwiching members 410 and 420A, includes a plurality of support portions 411 disposed to oppose the ends of a plurality of semiconductor modules 300 arranged in a row and spaces between the semiconductor modules 300, and the spring portions 412 and 413 extending from a plurality of support portions 411 in the arrangement direction of the semiconductor modules 300 (x direction) and abutting the cooling member 110, where a plurality of coupling members 440 couple the support portions 411 provided to the sandwiching member 410 and the sandwiching member 420A.

The coupling member 440 that presses the support portion 411 against the cooling member 110 is provided for each support portion 411 that has the spring portions 412 or the spring portions 412 and 413. The pressing force produced by the elastic deformation of the spring portions 412 and 413 can increased by the coupling members 440 pressing the support portions 411 that receive the reactive force from the spring portions 412 and 413. As a result, the quake resistance for holding the cooling members 110 and 210 can be improved.

Furthermore, as illustrated in FIGS. 11 and 12, the spring portions 412 extend in the arrangement direction of the semiconductor modules 300 (x direction) from the support portions 411 disposed to oppose the ends of a plurality of semiconductor modules 300 and the spaces between the semiconductor modules 300. The spring portion 412 extending from the support portion 411 abuts a region, opposing the semiconductor module 300, of the cooling member 110 and presses the region in the direction toward the semiconductor module 300. As a result, the cooling member 110 is pressed against the semiconductor modules 300 more uniformly, so that the semiconductor modules 300 can be cooled more effectively.

Note that, although the semiconductor device is provided with a plurality of semiconductor modules 300 in the above-described second and third exemplary modifications, the present invention can be applied also to one semiconductor module 300 as described above.

(C2) In the above (C1), as illustrated in FIGS. 4, 5, and 6, a pair of sandwiching members 410 and 420 includes a plurality of support portions 411 and 421 disposed to oppose the ends of a plurality of semiconductor modules 300 arranged in a row and spaces between the semiconductor modules 300, and the spring portions 412, 413, and 422 extending from a plurality of support portions 411 and 421 in the arrangement direction of the semiconductor modules 300 (x direction) and abutting the cooling members 110 and 210, where each coupling member 430 couple the opposing ones of the support portions 411 and 421 of the sandwiching members 410 and 420. As a result, both the cooling members 110 and 210 can be pressed more uniformly against the semiconductor modules 300.

(C3) In the above (C2), as illustrated in FIGS. 4 and 6, the support portion 411 includes the spring portions 412 and 413 at two ends thereof in the x direction, which is the module arrangement direction. By providing a plurality of support portions 411, having such spring portions 412 and 413, in the module arrangement direction, even when there is a plurality of semiconductor modules 300, the pressing force can be applied to each semiconductor module 300 by the spring portions 412. As a result, even when the cooling member 110 is warped or the semiconductor modules 300 vary in thickness, the semiconductor modules can be pressed with a uniform pressing force.

(C4) In the above (C2), as illustrated in FIGS. 4 to 6, the support portions 411 and 421 extend in the y direction orthogonal to the module arrangement direction, one end in the extending direction of the support portion 411 provided to the sandwiching member 410 and an end of the support portion 421 provided to the sandwiching member 420 and opposing the one end are coupled by the coupling member 430, and the other end in the extending direction of the support portion 411 provided to the sandwiching member 410 and an end of the support portion 421 provided to the sandwiching member 420 and opposing the other end are coupled by another coupling member 430. Since the ends, in the extending direction, of the support portions 411 and 421 are coupled by the coupling members 430, bending of the support portions 411 and 421 caused by the reactive force of the spring portions is suppressed, and the pressing force can be enhanced and applied uniformly.

(C5) In the above (C4), as illustrated in FIGS. 4 to 6, the coupling members 430 are provided separately from a pair of sandwiching members 410 and 420. Separately providing the coupling members 430 avoids interference of a coupling portion with other members during assembling as is the case when the coupling member 430 is integrated, and this gives excellent workability.

(C6) In the above (C5), as illustrated in FIG. 7, the coupling member 430 includes an engaging portion 430a that engages with the support portion 411 provided to the sandwiching member 410, an engaging portion 430a that engages with the support portion 421 provided to the sandwiching member 420, and a connecting portion 430b that connects the two engaging portions 430a. With this configuration, the coupling member 430 can be easily attached to the semiconductor device 100 by the engaging portions 430a engaging with the sandwiching members 410 and 420, and the workability can be improved.

(C7) In the above (C5), the rigidity of the coupling member 430 is higher than the rigidity of the support portions 411 and 421 provided to the sandwiching members 410 and 420. For example, as illustrated in FIG. 6, the coupling member 430 has the thickness t1 larger than the thicknesses t2 and t3 of the sandwiching members 410 and 420. Since the reactive force of the spring portions 412, 413, and 422 is applied to the coupling members 430 via the support portions 411 and 421, the pressing force applied to the cooling members 110 and 210 by the spring portions 412, 413, and 422 can be increased by increasing the rigidity of the coupling members 430.

(C8) In the above (C3), as illustrated in FIG. 6, the cooling member 110 has the flow path 114 and the flow path connection 111 provided at a place opposing the cooling member 210, the cooling member 210 has the flow path 214 and the flow path connection 211 to be connected to the flow path connection 111, and the spring portion 413 of the sandwiching member 410 abuts the sandwiching member-opposing surface (cover 113) of the cooling member 110 in a region where the flow path connection 111 is provided. Since the spring portions 413 are configured to abut the sandwiching member-opposing surface (cover 113) of the cooling member 110, the pressing force of the spring portions 413 keeps the appropriate connected state between the flow path connection 111 and the flow path connection 211 against the refrigerant pressure.

(C9) In the above (C8), as illustrated in FIG. 6, in a plurality of the spring portions 412 and 413 of the sandwiching member 410 including the spring portion 413 abutting the sandwiching member-opposing surface (cover 113), the spring constant of the spring portion 413 abutting the sandwiching member-opposing surface is set to a value different from the spring constant of the spring portion 412. With the spring portion 413 having a spring constant different from the spring constant of the spring portion 412, the pressing force applied to the region of the opposing portion 113b of the cooling member 110 and the pressing force applied to the region where the flow path connection 111 is provided can be set individually. In the example illustrated in FIG. 6, the region where the flow path connection 111 is provided has low rigidity because no fin 115 is provided inside the cover 113, and giving a low spring constant to the abutting spring portion 413 prevents deformation of the cover 113.

(C10) In the above (C1), as illustrated in FIGS. 5 and 6, the cooling member 110 includes the opposing portions 113b opposing the semiconductor modules 300 and the recessed portions 113a as flexible portions provided at two ends, in the module arrangement direction (x direction), of the opposing portions 113b, and the cooling member 210 includes the opposing portions 213b opposing the semiconductor modules 300 and the recessed portions 213a as flexible portions provided at two ends, in the module arrangement direction (x direction), of the opposing portions 213b. By the cooling members 110 and 210 bending at the recessed portions 113a and 213a, respectively, depending on the variation in thickness of a plurality of semiconductor modules 300, the cooling members 110 and 210 can be uniformly pressed against the semiconductor modules 300.

The embodiments and various exemplary modifications described above are merely examples, and the present invention is not limited to the contents thereof as long as the features of the invention are not impaired. Although various embodiments and exemplary modifications have been described above, the present invention is not limited to the contents thereof. Other aspects conceivable within the scope of the technical idea of the present invention are also included within the scope of the present invention.

### REFERENCE SIGNS LIST

100, 100A, 100B semiconductor device
110, 210 cooling member
111, 211 flow path connection
113 cover
113a, 213a recessed portion
113b, 213b opposing portion
300 semiconductor module
410, 410A, 420, 420A sandwiching member
411, 421 support portion
412, 413, 422 spring portion
415 coupling portion
430, 440 coupling member
430a, 440a engaging portion
430b, 440b connecting portion

1. A semiconductor device comprising:
one or more semiconductor modules arranged in a row;
a pair of cooling members disposed so as to sandwich the one or more semiconductor modules arranged in a row and configured to cool the semiconductor modules;
a pair of sandwiching members each disposed on an opposite side of the semiconductor module across a corresponding one of the pair of cooling members to oppose the corresponding one of the pair of cooling members; and
a coupling portion that couples the pair of sandwiching members to each other and presses each of the pair of sandwiching members against the opposing one of the cooling members, wherein
at least one of the pair of sandwiching members includes a plurality of support portions disposed to oppose ends of the one or more semiconductor modules arranged in a row and a space between the semiconductor modules, and a spring portion extending from each of the plurality of support portions in an arrangement direction of the semiconductor modules and abutting the cooling member, and
the coupling portion couples the support portion provided to the one of the pair of sandwiching members and another sandwiching member.

2. The semiconductor device according to claim 1, wherein
each of the pair of sandwiching members includes a plurality of support portions disposed to oppose ends of the one or more semiconductor modules arranged in a row and a space between the semiconductor modules, and a spring portion extending from each of the plurality of support portions in an arrangement direction of the semiconductor modules and abutting the cooling member, and
the coupling portion includes, for each of the support portions, a coupling member that couples the support portions opposing each other of the pair of sandwiching members.

3. The semiconductor device according to claim 2, wherein the support portion includes the spring portions at two ends of the support portion in the arrangement direction.

4. The semiconductor device according to claim 2, wherein
the support portion extends in a direction orthogonal to the arrangement direction,
one end in an extending direction of the support portion provided to one of the pair of sandwiching members is coupled to an end of the support portion provided to another one of the pair of sandwiching members and opposing the one end by one of the plurality of coupling members, and
another end in the extending direction of the support portion provided to the one of the pair of sandwiching members is coupled to an end of the support portion provided to the other one of the pair of sandwiching members and opposing the other end by other one of the plurality of coupling members.

5. The semiconductor device according to claim 4, wherein the coupling member is formed separately from the pair of sandwiching members.

6. The semiconductor device according to claim 5, wherein the coupling member includes
a first engaging portion that engages with the support portion provided to the one of the pair of sandwiching members,
a second engaging portion that engages with the support portion provided to the other one of the pair of sandwiching members, and
a connecting portion that connects the first engaging portion and the second engaging portion.

7. The semiconductor device according to claim 5, wherein rigidity of the coupling member is higher than rigidity of the support portions provided to the pair of sandwiching members.

8. The semiconductor device according to claim 3, wherein one of the pair of cooling members includes a first refrigerant flow path and a first flow path connection provided at a place opposing another one of the cooling members,
the other one of the cooling members has a second refrigerant flow path and a second flow path connection to be connected to the first flow path connection, and
at least one of a sandwiching member-opposing surface in a region, where the first flow path connection is provided, in the one of the pair of cooling members and a sandwiching member-opposing surface in a region, where the second flow path connection is provided, of the other one of the cooling members is abutted by one of a plurality of the spring portions included in the sandwiching member that opposes the sandwiching member-opposing surface.

9. The semiconductor device according to claim 8, wherein in the plurality of spring portions of the sandwiching member including the spring portion abutting the sandwiching member-opposing surface, a spring constant of the spring portion abutting the sandwiching member-opposing surface is set to a value different from a spring constant of the spring portion other than the spring portion abutting the sandwiching member-opposing surface.

10. The semiconductor device according to claim 1, wherein each of the pair of cooling members includes an opposing portion opposing the semiconductor module, and a flexible portion provided at two ends of the opposing portion in the arrangement direction.
